(19) United States
(12) Patent Application Publication
(10) Pub. No.: US 2025/0237715 A1
(43) Pub. Date: Jul. 24, 2025

(54) COMPENSATION MECHANISM FOR EXTENDED LINEARITY OF MAGNETIC FIELD SENSORS

(71) Applicant: Allegro MicroSystems, LLC, Manchester, NH (US)

(72) Inventors: Andres Kasulin, CABA (AR); Salvador Ortiz, CABA (AR); Hernán D. Romero, Buenos Aires (AR)

(73) Assignee: Allegro MicroSystems, LLC, Manchester, NH (US)

(21) Appl. No.: 18/417,392

(22) Filed: Jan. 19, 2024

(51) Int. Cl. G01R 33/00; G01R 33/06

(52) U.S. Cl. CPC G01R 33/0082; G01R 33/06

(57) ABSTRACT

A device, comprising: a magnetic field sensor including: (i) one or more first magnetic field sensing elements arranged to produce a first magnetic field signal in response to a magnetic field, (ii) a programmable gain amplifier (PGA) that is configured to amplify the first magnetic field signal to produce an amplified signal, and (iii) a first circuitry that is configured to generate an output signal based on the amplified signal; and a compensation circuit including: (i) one or more second magnetic field sensing elements that are arranged to produce a second magnetic field signal in response to the magnetic field, and (ii) a second circuitry that is configured to adjust a gain of the PGA based on the second magnetic field signal, thereby causing a gain of the PGA to be increased or decreased based on the magnetic field at one or more second magnetic field sensing elements.

### BACKGROUND

As is known, sensors are used to perform various functions in a variety of applications. Some sensors include one or more electromagnetic flux sensing elements, such as a Hall effect element, a magnetoresistive element, or a receiving coil to sense an electromagnetic flux associated with proximity or motion of a target object. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a device is provided, comprising: a magnetic field sensor including: (i) one or more first magnetic field sensing elements arranged to produce a first magnetic field signal in response to a magnetic field, (ii) a programmable gain amplifier (PGA) that is configured to amplify the first magnetic field signal to produce an amplified signal, and (iii) a first circuitry that is configured to generate an output signal based on the amplified signal; and a compensation circuit including: (i) one or more second magnetic field sensing elements that are arranged to produce a second magnetic field signal in response to the magnetic field, and (ii) a second circuitry that is configured to generate a gain adjustment signal based on the second magnetic field signal, the second circuitry being configured to apply the gain adjustment signal at a control terminal of the PGA, wherein the gain adjustment signal is generated based on a map that maps each of a plurality of values of the second magnetic field signal to a respective value of the gain adjustment signal, the map being implemented by the second circuitry, and wherein the magnetic field sensor and the compensation circuit are disposed in a same package.

According to aspects of the disclosure, a device, comprising: a magnetic field sensor including a first channel, a second channel, and a first circuitry, wherein: (i) the first channel includes one or more first magnetic field sensing elements that are configured to produce a first magnetic field signal in response to a magnetic field and a first programmable gain amplifier (PGA) that is configured to amplify the first magnetic field signal to produce a first amplified signal, (ii) the second channel includes one or more second magnetic field sensing elements that are configured to produce a second magnetic field signal in response to the magnetic field and a second PGA that is configured to amplify the second magnetic field signal to produce a second amplified signal, and (iii) the first circuitry is configured to generate an output signal based on the first amplified signal and the second amplified signal; and a compensation circuit including one or more third magnetic field sensing elements that are arranged to produce a third magnetic field signal in response to the magnetic field, and a second circuitry that is configured to generate, based on the third magnetic field signal, a first gain adjustment signal and a second gain adjustment signal, the second circuitry being configured to apply the first gain adjustment signal at a first control terminal of the first PGA, the second circuitry being configured to apply the second gain adjustment signal at a second control terminal of the second PGA, wherein for at least one value of the third magnetic field signal, the first gain adjustment signal and the second gain adjustment signal have different values.

According to aspects of the disclosure, a device is provided, comprising: a magnetic field sensor including: (i) one or more first magnetic field sensing elements arranged to produce a first magnetic field signal in response to a magnetic field, (ii) a programmable gain amplifier (PGA) that is configured to amplify the first magnetic field signal to produce an amplified signal, and (iii) a first circuitry that is configured to generate an output signal based on the amplified signal; and a compensation circuit including: (i) one or more second magnetic field sensing elements that are arranged to produce a second magnetic field signal in response to the magnetic field, and (ii) a second circuitry that is configured to adjust a gain of the PGA based on the second magnetic field signal, thereby causing a gain of the PGA to be increased or decreased based on a strength of the magnetic field at a location of the one or more second magnetic field sensing elements.

According to aspects of the disclosure, a system is provided, comprising: means for generating a first magnetic field signal in response to a magnetic field; means for generating a second magnetic field signal in response to the magnetic field, and means for generating an output signal at least in part by adjusting a gain of the first magnetic field signal based on the second magnetic field signal, wherein the adjusting is performed based on a map that maps each of a plurality of ranges of the second magnetic field signal to a respective value of a gain adjustment signal applied at a control terminal of a programmable gain amplifier (PGA), the PGA being arranged to amplify the first magnetic field signal.

### BRIEF DESCRIPTION OF THE DRAWINGS

The foregoing features may be more fully understood from the following description of the drawings in which:

FIG. 1 is a diagram of an example of a sensing system, according to aspects of the disclosure;

FIG. 2A is a diagram of an example of one possible implementation of the sensing system of FIG. 1, according to aspects of the disclosure;

FIG. 2B is a diagram of an example of another possible implementation of the sensing system of FIG. 1, according to aspects of the disclosure;

FIG. 2C is a diagram of an example of a data structure, according to aspects of the disclosure;

FIG. 2D is a diagram of an example of a data structure, according to aspects of the disclosure;

FIG. 2E is a graph illustrating an example of different signal ranges, according to aspects of the disclosure;

FIG. 2F is a flowchart of an example of a process that is performed by the sensing system implementation of FIG. 2A, according to aspects of the disclosure;

FIG. 2G is a flowchart of an example of a process that is performed by the sensing system implementation of FIG. 2B, according to aspects of the disclosure;

FIG. 3A is a graph illustrating aspects of the operation of the sensing system implementation of FIG. 2A, according to aspects of the disclosure;

FIG. 3B is a graph illustrating aspects of the operation of the sensing system implementation of FIG. 2A, according to aspects of the disclosure; and

FIG. 4 is a diagram of an example of a sensor, according to aspects of the disclosure;

### DETAILED DESCRIPTION

In one aspect, a magnetic field sensor is provided that includes a first sensing circuit and a second sensing circuit. The first sensing circuit includes a first set of one or more magnetic field sensing elements, and the second sensing circuit includes a second set of one or more magnetic field sensing elements. The first set of magnetic field sensing elements is arranged to generate a first magnetic field signal in response to a magnetic field. The second set of magnetic field sensing elements is arranged to generate a second magnetic field sensing signal in response to the same magnetic field. When the magnetic field sensor is a current sensor, the magnetic field may be generated by a conductor that carries the electrical current that is being measured by the magnetic field sensor. The first magnetic field signal is used, by the first sensing circuit, to generate an output signal (e.g., a signal indicative of the level of an electrical current). The second magnetic field signal is used, by the second sensing circuit, to dynamically control the gain of the first sensing circuit, which improves the linearity of the response of the first sensing circuit. The first sensing circuit and the second sensing circuit may be formed on the same substrate and/or packaged inside the same (semiconductor) packaging. Under the nomenclature of the present disclosure, the first sensing circuit is referred to as a “sensor” and the second sensing circuit is referred to as a “compensation circuit”.

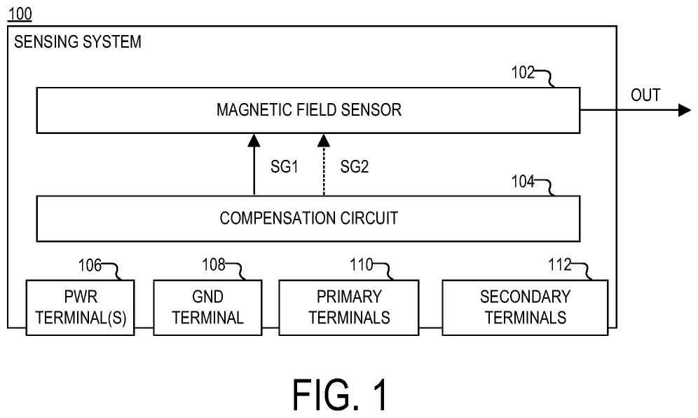

FIG. 1 is a diagram of an example of a sensing system 100, according to aspects of the disclosure. The sensing system 100 may include a magnetic field sensor 102 (hereinafter “sensor 102”), a compensation circuit 104 (hereinafter “circuit 104”), one or more power terminals 106, a ground terminal 108, one or more primary terminals 110, and one or more secondary terminals 112.

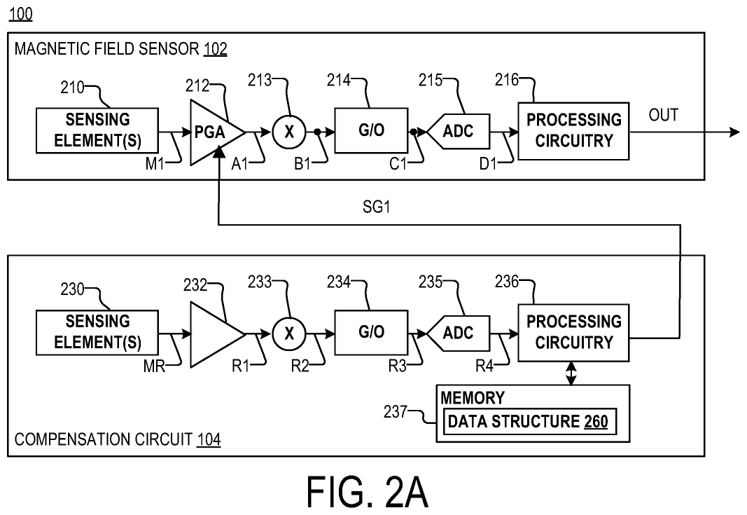

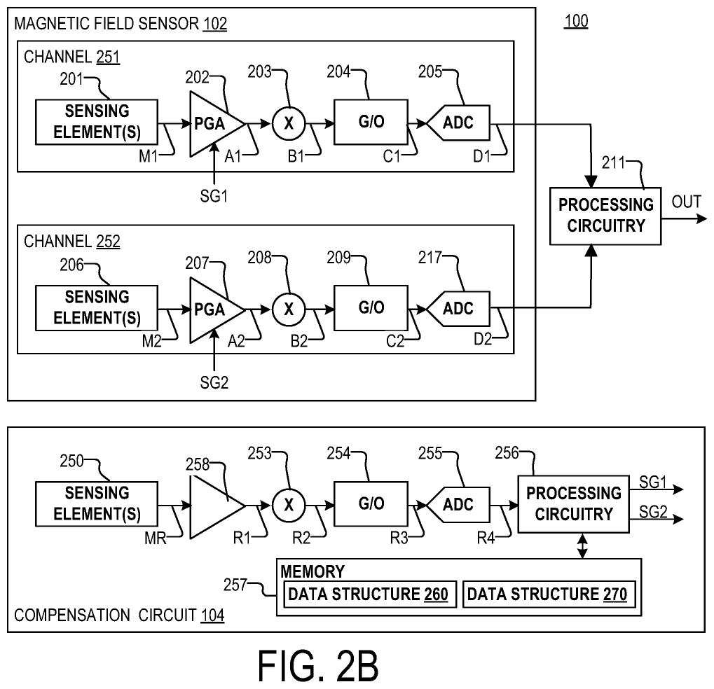

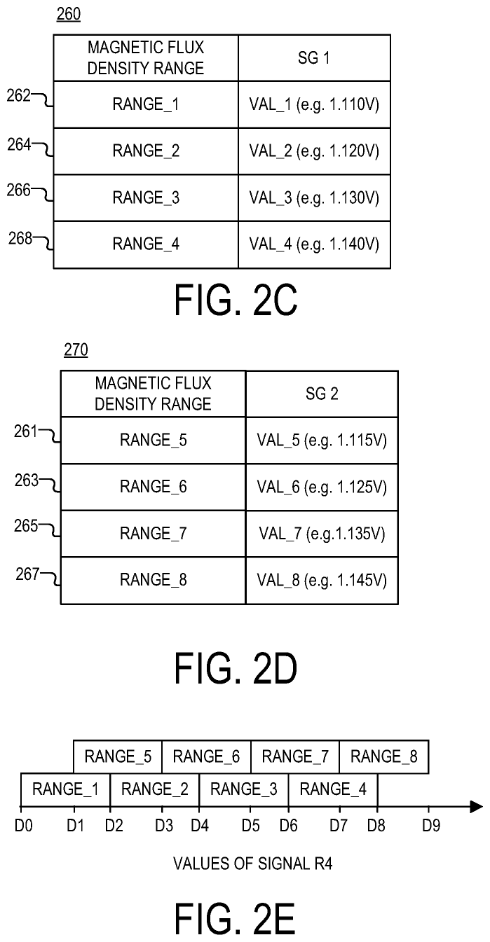

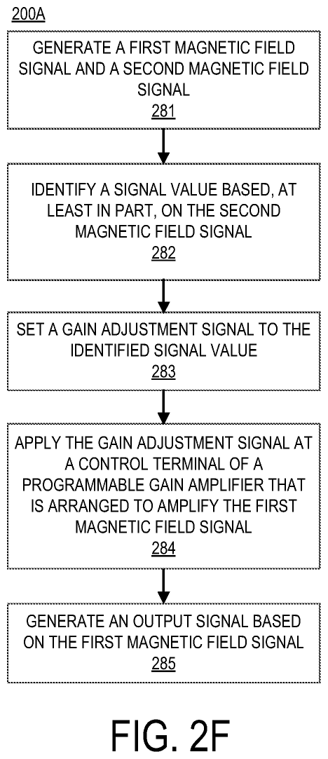

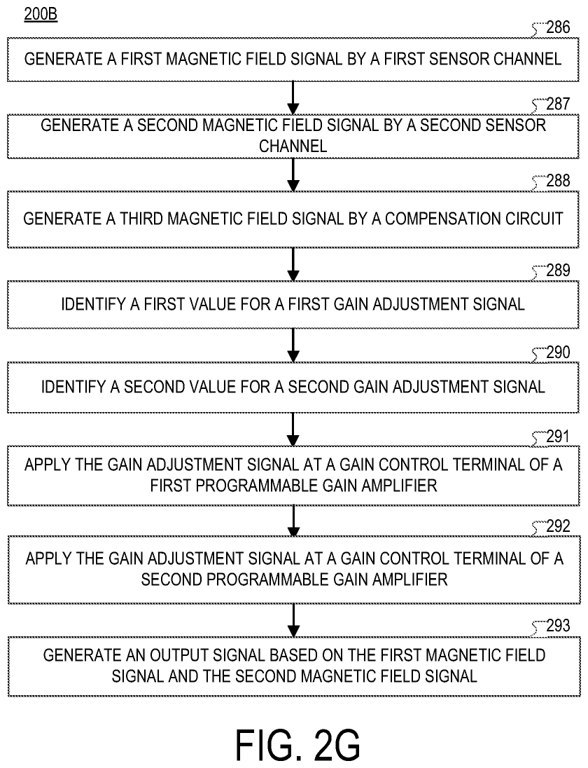

Sensor 102 may include any suitable type of magnetic field sensor. By way of example, sensor 102 may include an angle sensor, a position sensor, or a current sensor. In operation, sensor 102 may detect a magnetic field and output a signal OUT that is generated in response to the magnetic field. The signal OUT may indicate the position of a target, the level of an electrical current through a conductor, the angular position of a target, the speed of a target, the acceleration of a target, and/or any other suitable parameter. Circuit 104 may include electronic circuitry that is configured to adjust the gain of sensor 102 to improve the linearity of the response of sensor 102. In operation, circuit 104 may sense the same magnetic field that is being sensed by sensor 102 and generate a gain adjustment signal SG1 in response. Optionally, circuit 104 may also generate a gain adjustment signal SG2 in response to the magnetic field. Signals SG1 and SG2 may control the gain of different channels inside sensor 102. The manner in which signals SG1 and SG2 are generated and used is discussed further below with respect to FIGS. 2A-B.

The power terminals 106 may be arranged to provide power to sensor 102 and circuit 104. Ground terminal 108, may be configured to connect sensor 102 and circuit 104 to ground. Terminals 110 may include one or more terminals that are configured to store and receive data from sensor 102. In one example, terminals 110 may be used to output the signal OUT. Additionally or alternatively, terminals 110 may be used to store data in sensor 102. For instance, terminals 110 may be used to update the firmware of sensor 102 and/or for any other suitable purpose. Terminals 112 may include one or more terminals that are configured to store and receive data from circuit 104. In one example, terminals 112 may be used to update the firmware of circuit 104. In another example, terminals 112 may be used by circuit 104 to receive updates to one or more data structures, such as data structures 260 and 270 (shown in FIGS. 2C-D), which may be stored in the memory of compensation circuit 104.

In the example of FIG. 1, sensing system 100 is housed in a unitary sensor package. For example, sensor 102 and circuit 104 may be formed on the same substrate (e.g., a silicon substrate) and encapsulated together in the same semiconductor (or other) package. As another example, sensor 102 and circuit 104 may be formed on different semiconductor dies (e.g., silicon dies) and encapsulated together in the same semiconductor package. When sensor 102 and circuit 104 are formed in the same package, signals SG1 and SG2 may be transmitted to sensor 102 via conductors that are internal to the package. Although, in the present example, sensor 102 and circuit 104 are housed in the same (semiconductor) package, alternative implementations are possible in which they are housed in different (semiconductor) packages. Stated succinctly, the present disclosure is not limited to any specific packaging of sensor 102 and circuit 104.

FIG. 2A is a diagram of sensing system 100, in accordance with one implementation. In the example of FIG. 2A, sensor 102 includes one or more magnetic field sensing elements 210 (hereinafter “sensing elements 210”), a programmable gain amplifier (PGA) 212, a demodulator 213, a gain/offset adjustment circuit 214, an analog-to-digital converter (ADC) 215, and a processing circuitry 216. In operation, sensing elements 210 may generate a magnetic field signal M1 in response to a given magnetic field. PGA 212 may amplify the magnetic field signal M1 to produce a signal A1. Demodulator 213 may demodulate signal A1 to produce a signal B1. Gain/offset adjustment circuit 214 may generate an adjusted signal C1 by adjusting at least one of the gain and/or offset of signal B1. ADC 215 may digitize signal C1 to produce a digitized signal D1. The processing circuitry 216 may generate signal OUT based on the digitized signal D1. The processing circuitry 216 may include a general-purpose processor, a special-purpose processor, and/or any other suitable type of electronic circuitry.

In the example of FIG. 2A, circuit 104 includes one or more magnetic field sensing elements 230 (hereinafter “sensing elements 230”), an amplifier 232, a demodulator 233, a gain/offset adjustment circuit 234, an analog-to-digital converter (ADC) 235, a processing circuitry 236, and a memory 237. In operation, sensing elements 230 may generate a magnetic field signal MR in response to the given magnetic field. Amplifier 232 may amplify the magnetic field signal MR to produce a signal R1. Demodulator 233 may demodulate signal R1 to produce a signal R2. Gain/offset adjustment circuit 234 may generate an adjusted signal R3 by adjusting at least one of the gain and/or offset of signal R2. ADC 235 may digitize signal R3 to produce a digitized signal R4. Processing circuitry 236 may generate signal SG1 based on the digitized signal R4. Signal SG1 may be applied at a gain control terminal of PGA 212 and used to adjust the gain of PGA 212. Signal SG1 may be generated in the manner discussed further below with respect to FIGS. 2C-G.

Processing circuitry 236 may include a general-purpose processor, a special-purpose processor, and/or any other suitable type of electronic circuitry. Memory 237 may include any suitable type of volatile or non-volatile memory. By way of example, memory 237 may include one or more of a flash memory, an electronically erasable programmable read-only memory (EEPROM), or a double data rate (DDR) random-access memory (RAM). Memory 237 may store a data structure 260 that is used by processing circuitry 236 to generate signal SG1. Data structure 260 is discussed further below with respect to FIG. 2C. The term “data structure”, as used throughout the disclosure, may refer to a plurality of locations in a memory, such as memory 237 (shown in FIG. 2A) or memory 257 (shown in FIG. 2B). The locations may or may not be contiguous. The use of the term “data structure” is not intended to imply the performance of any specific memory management operations beyond reading and possibly storing data in the memory locations that together constitute the data structure.

Processing circuitry 236 may set the gain of PGA 212 based on the value of signal R4, which is generated by sensing elements 230. If the value of signal R4 belongs in a first range (shown in FIG. 2C), the value of signal SG1 may be set to 0.110V. If the value of signal R4 belongs in a second range (shown in FIG. 2C), the value of signal SG1 may be set to 0.120V. If the value of signal R4 belongs in a third range (shown in FIG. 2C), the value of signal SG1 may be set to 0.130V. If the value of signal R4 belongs in a fourth range (shown in FIG. 2C), the value of signal SG1 may be set to 0.140V. Although, in the present example, the gain of PGA 212 (and/or the value of signal SG1) is set based on signal R4, alternative implementations are possible in which the gain of PGA 212 (and/or the value of signal SG1) is set based on signal MR and/or another signal that is at least in part generated based on signal MR (or at least in part generated by sensing elements 230).

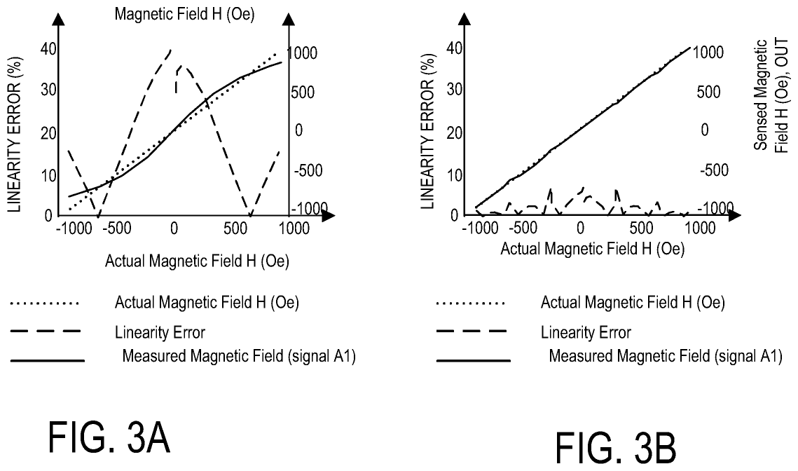

As can be readily appreciated, setting signal SG1 to the first value may cause PGA 212 to apply a first gain to signal M1, setting signal SG1 to the second value may cause PGA 212 to apply a second gain to signal M1, setting signal SG1 to the third value may cause PGA 212 to apply a third gain to signal M1, and setting signal SG to a fourth value may cause PGA 212 to apply a fourth gain to signal M1. The first, second, third, and fourth gains may be different from each other. As discussed further below with respect to FIG. 3B, dynamically changing the gain of PGA 212 based on signal SG1 may improve the linearity of signal M1.

Under the nomenclature of the present disclosure, the value of a signal belongs in a range at least when the value is greater than the lower bound of the range and smaller than the upper bound of the range. For example, the value of the signal may belong in the range if it is greater than the lower bound and less than or equal to the upper bound. As another example, the value of the signal may belong in the range when the value is greater than or equal to the lower bound and less than the upper bound. Since the upper bound of one range may be the lower bound of another, the resolution of cases when the value of a signal is equal to a bound that is shared between two different ranges may follow a convention that is implementation-specific.

FIG. 2B is a diagram of sensing system 100, in accordance with another implementation. In the example of FIG. 2B, sensor 102 may include a channel 251, a channel 252, and a processing circuitry 211. Channel 251 may include one or more magnetic field sensing elements 201 (hereinafter “sensing elements 201”), a PGA 202, a demodulator 203, a gain/offset adjustment circuit 204, and an analog-to-digital converter (ADC) 205. Channel 252 may include one or more magnetic field sensing elements 206 (hereinafter “sensing elements 206”), a PGA 207, a demodulator 208, a gain/offset adjustment circuit 209, and an analog-to-digital converter (ADC) 217.

The operation of channel 251 is now described in further detail. Sensing elements 201 may generate a magnetic field signal M1 in response to a given magnetic field. PGA 202 may amplify the magnetic field signal M1 to produce a signal A1. Demodulator 203 may demodulate signal A1 to produce a signal B1. Gain/offset adjustment circuit 204 may generate an adjusted signal C1 by adjusting at least one of the gain and/or offset of signal B1. ADC 205 may digitize signal C1 to produce a digitized signal D1.

The operation of channel 252 is now described in further detail. Sensing elements 206 may generate a magnetic field signal M2 in response to the given magnetic field. PGA 207 may amplify the magnetic field signal M2 to produce a signal A2. Demodulator 208 may demodulate signal A2 to produce a signal B2. Gain/offset adjustment circuit 209 may generate an adjusted signal C2 by adjusting at least one of the gain and/or offset of signal B2. ADC 217 may digitize signal C2 to produce a digitized signal D2.

Processing circuitry 211 may generate the signal OUT based on signals D1 and D2. It will be understood that the present disclosure is not limited to any specific manner for generating signal OUT as those of ordinary skill in the art will readily recognize that there are a number of ways in which the outputs of different channels in a multi-channel magnetic field sensor can be combined to generate an output signal. The processing circuitry 211 may include a general-purpose processor, a special-purpose processor, and/or any other suitable type of electronic circuitry.

In the example of FIG. 2B, circuit 104 includes one or more magnetic field sensing elements 250 (hereinafter “sensing elements 250”), an amplifier 258, a demodulator 253, a gain/offset adjustment circuit 254, an analog-to-digital converter (ADC) 255, a processing circuitry 256, and a memory 257. In operation, sensing elements 250 may generate a magnetic field signal MR in response to the given magnetic field. Amplifier 258 may amplify the magnetic field signal MR to produce a signal R1. Demodulator 253 may demodulate signal R1 to produce a signal R2. Gain/offset adjustment circuit 254 may generate an adjusted signal R3 by adjusting at least one of the gain and/or offset of signal R2. ADC 255 may digitize signal R3 to produce a digitized signal R4. Processing circuitry 256 may generate signals SG1 and SG2 based on the digitized signal R4. Signal SG1 may be applied at a gain control terminal of PGA 202 and used to adjust the gain of PGA 202. Signal SG2 may be applied at a gain control terminal of PGA 207 and used to adjust the gain of PGA 207.

Processing circuitry 256 may include a general-purpose processor, a special-purpose processor, and/or any other suitable type of electronic circuitry. Memory 257 may include any suitable type of volatile or non-volatile memory. By way of example, memory 257 may include one or more of a flash memory, an electronically erasable programmable read-only memory (EEPROM), a double data rate (DDR) random-access memory (RAM). Memory 257 may store data structures 260 and 270 that are used by processing circuitry 256 to generate signals SG1 and SG2. Data structures 260 and 270 are discussed further below with respect to FIG. 2C and FIG. 2D, respectively.

Processing circuitry 256 may set the value of signal SG1 based on signal R4. The gain that is applied by PGA 202 to signal M1 may be proportional to the value of signal SG1. In other words, by setting the value of signal SG1, processing circuitry 256 may dynamically control the gain of PGA 202. If the value of signal R4 belongs in a first range (shown in FIG. 2C), the value of signal SG1 may be set to 0.110V. If the value of signal R4 belongs in a second range (shown in FIG. 2C), the value of signal SG1 may be set to 0.120V. If the value of signal R4 belongs in a third range (shown in FIG. 2C), the value of signal SG1) may be set to 0.130V. If the value of signal R4 belongs in a fourth range (shown in FIG. 2C), the value of signal SG1 may be set to 0.140V. Although, in the present example, the gain of PGA 202 (and/or the value of signal SG1) is set based on signal R4, alternative implementations are possible in which the gain of PGA 202 (and/or the value of signal SG1) is set based on signal MR and/or another signal that is at least in part generated based on signal MR (or at least in part generated by sensing elements 250).

Processing circuitry 256 may set the value of signal SG2 based on signal R4. The gain that is applied by PGA 207 to signal M2 may be proportional to the value of signal SG2. In other words, by setting the value of signal SG2, processing circuitry 256 may dynamically control the gain of PGA 207. If the value of signal R4 belongs in a fifth range (shown in FIG. 2D), the value of signal SG2 may be set to 0.115V. If the value of signal R4 belongs in a sixth range (shown in FIG. 2D), the value of signal SG2) may be set to 0.125V. If the value of signal R4 belongs in a seventh range (shown in FIG. 2D), the value of signal SG2 may be set to 0.135V. If the value of signal R4 belongs in an eighth range (shown in FIG. 2D), the value of signal SG2 may be set to 0.145V. Although, in the present example, the gain of PGA 207 (and/or the value of signal SG2) is set based on signal R4, alternative implementations are possible in which the gain of PGA 207 (and/or the value of signal SG2) is set based on signal MR and/or another signal that is at least in part based on signal MR (or at least in part generated by sensing elements 250).

FIG. 2C is a diagram of data structure 260, according to aspects of the disclosure. As illustrated, data structure 260 may include entries 262-268. In some implementations, data structure 260 may be used by processing circuitry 236 and 256 to determine the value of signal SG1. Entry 262 indicates that when the magnetic flux density that is incident on sensing elements 230 (or sensing elements 250) is in a first range, signal SG1 should have a first value (e.g., 1.110V). Entry 264 indicates that when the magnetic flux density that is incident on sensing elements 230 (or sensing elements 250) is in a second range, signal SG1 should have a second value (e.g., 1.120V). Entry 266 indicates that when the magnetic flux density that is incident on sensing elements 230 (or sensing elements 250) is in a third range, signal SG1 should have a third value (e.g., 1.130V). And entry 268 indicates that when the magnetic flux density that is incident on sensing elements 230 (or sensing elements 250) is in a fourth range, signal SG1 should have a fourth value (e.g., 1.140V). The magnetic flux density that is incident on sensing elements 230 (or sensing elements 250), may be expressed in terms of the value of signal R4 (shown in FIGS. 2A and 2B). In this regard, in some implementations, each of entries 262-268 may map different ranges for the value of signal R4 to a corresponding value of signal SG1. However, alternative implementations are possible in which the magnetic flux density that is incident on sensing elements 230 (or sensing elements 250) is expressed in terms of the values of any signal that is generated, at least in part, by sensing elements 230 (or sensing elements 250).

FIG. 2D is a diagram of data structure 270, according to aspects of the disclosure. As illustrated, data structure 270 may include entries 261-267. In some implementations, data structure 270 may be used by processing circuitry 236 and 256 to determine the value of signal SG2. Entry 261 indicates that when the magnetic flux density that is incident on sensing elements 230 (or sensing elements 250) is in a fifth range, signal SG2 should have a first value (e.g., 1.115V). Entry 263 indicates that when the magnetic flux density that is incident on sensing elements 230 (or sensing elements 250) is in a sixth range, signal SG2 should have a second value (e.g., 1.125V). Entry 265 indicates that when the magnetic flux density that is incident on sensing elements 230 (or sensing elements 250) is in a seventh range, signal SG2 should have a third value (e.g., 1.135V). And entry 267 indicates that when the magnetic flux density that is incident on sensing elements 230 (or sensing elements 250) is in an eighth range, signal SG2 should have a fourth value (e.g., 1.145V). The magnetic flux density that is incident on sensing elements 230 (or sensing elements 250), may be expressed in terms of the value of signal R4 (shown in FIGS. 2A and 2B). In this regard, in some implementations, each of entries 261-267 may map different ranges for the value of signal R4 to a corresponding value of signal SG2. However, alternative implementations are possible in which the magnetic flux density that is incident on sensing elements 230 (or sensing elements 250) is expressed in terms of the values of any signal that is generated, at least in part, by sensing elements 230 (or sensing elements 250). Although, in the present example, data structures 260 and 270 are depicted as separate entities, alternative implementations are possible in which data structures 260 and 270 are integrated into a single data structure.

FIG. 2E is a plot showing the relationship between the ranges identified in data structures 260 and 270. The boundaries of the ranges that are shown in FIGS. 2C-D are denoted with alphanumeric characters D0 through D9, where each alphanumeric character D0-D9 corresponds to a different value of signal R4, and D0<D1<D2<D3<D4<D5<D6<D7<D8<D8<D9. In the example of FIG. 2E, the first range extends between values D0 and D2, the second range extends between values D2 and D4, the third range extends between values D4 and D6, the fourth range extends between values D6 and D8, the fifth range extends between values D1 and D3, the sixth range extends between values D3 and D5, the seventh range extends between values D5 and D7, and the eight range extends between values D7 and D9. As illustrated, the first, second, third, and fourth ranges may be mutually exclusive, and as such, no overlap may be present between them. The fifth, sixth, seventh, and eighth ranges may also be mutually exclusive, and as such, no overlap may be present between them. In another aspect, FIG. 2E shows that the fifth range may overlap with the first and second ranges, the sixth range may overlap with the second and third ranges, the seventh range may overlap with the third and fourth ranges, and the eighth range may partially overlap with the fourth range.

FIG. 2F is a flowchart of an example of a process 200A, according to aspects of the disclosure. According to the example of FIG. 2F, process 200A is performed by the implementation of sensing system 100 which is shown in FIG. 2A. However, the present disclosure is not limited to any specific entity performing process 200A. FIG. 2F is provided as an example only. At least some of the steps shown in FIG. 2F may be performed in parallel, in a different order, or altogether omitted.

At step 281, a first magnetic field signal and a second magnetic field signal are generated by different sets of magnetic field sensing elements. According to the present example, the first magnetic field signal is signal M1 and the second magnetic field signal is signal MR, both of which are shown in FIG. 2A. As noted above, signals MR and M1 are generated in response to the same magnetic field—i.e., a magnetic field (or a combination of magnetic fields) that is incident on sensing system 100.

At step 282, processing circuitry 236 identifies a signal value based, at least in part, on the second magnetic field signal. The signal value may be identified based on a data structure, such as data structure 260. In the example of sensing system 100, the signal value may be identified by: (i) determining the value of signal R4, (ii) performing a search of data structure 260 based on the value of signal R4, and (iii) identifying, as a result of the search, a signal value that is mapped to the range in which the value of signal R4 belongs. According to the present example, the signal value is identified based on signal R4, which is itself based on signal MR. However, alternative implementations are possible in which the signal value is identified based on signal MR and/or any other signal that is at least in part derived from the signal MR, such as one of the signals R1, R2, and R3 for example.

At step 283, processing circuitry 236 sets the value of a gain adjustment signal to the signal value that is identified at step 282. According to the present example, signal SG1 is set to the signal value identified at step 282.

At step 284, the gain adjustment signal is applied at the gain control terminal of a programmable gain amplifier that is used to amplify the first magnetic field signal. According to the present example, signal SG1 is applied at the gain control terminal of PGA 212.

At step 285, processing circuitry 216 generates an output signal based on the first magnetic field signal. The output signal is generated after the gain of the first magnetic field signal is adjusted. According to the present example, the output signal is signal OUT (shown in FIG. 2A).

Although in the example of FIG. 2F a lookup table (i.e., data structure 260) is used to identify the value of signal SG1, alternative implementations are possible in which digital logic is used to implement the mapping between values of signal R4 and corresponding values of signal SG1. Such digital logic may be part of processing circuitry 236 and it may map each of a plurality of ranges for the value of signal R4 to a different respective value of signal SG1. Furthermore, in some implementations, the value of signal SG1 may be set by using analog circuitry that is part of processing circuitry 236, and which is arranged to map each of a plurality of ranges for the value of signal R4 to a different respective value of signal SG1. Stated succinctly, the present disclosure is not limited to any specific implementation of processing circuitry 236 or any specific method for executing step 282. As used throughout the disclosure, the phrase “a map that maps each of a plurality of values of a magnetic field signal to a respective value of a gain adjustment signal” may refer to a data structure, digital circuitry, or analog circuitry. Although in the example of FIG. 2F the value of signal SG1 is determined based on signal R4, alternative implementations are possible in which the value of signal SG1 is determined based on signal MR and/or any other signal that is at least in part generated by sensing elements 230.

FIG. 2G is a flowchart of an example of a process 200B, according to aspects of the disclosure. According to the example of FIG. 2E, process 200B is performed by the implementation of sensing system 100 which is shown in FIG. 2B. However, the present disclosure is not limited to any specific entity performing process 200B. FIG. 2G is provided as an example only. At least some of the steps shown in FIG. 2G may be performed in parallel, in a different order, or altogether omitted.

At step 286, a first magnetic field signal is generated by a first sensor channel. According to the present example, signal M1 is generated by sensing elements 201, which are part of channel 251.

At step 287, a second magnetic field signal is generated by a second sensor channel. According to the present example, signal M2 is generated by sensing elements 206, which are part of channel 252.

At step 288, a third magnetic field signal is generated by using a compensation circuit. According to the present example, signal MR is generated by sensing elements 250 of circuit 104. The first, second, and third magnetic field magnetic field signals may generated in response to the same magnetic field—i.e., a magnetic field (or a combination of magnetic fields) that is incident on sensing system 100.

At step 289, processing circuitry 256 identifies a first signal value and sets a first gain adjustment signal to the identified first signal value. The first signal value may be identified based on a first data structure, such as data structure 260. In the example of sensing system 100, the first signal value may be identified by: (i) identifying the value of signal R4, (ii) performing a search of data structure 260 based on the value of signal R4, (iii) identifying, as a result of the search, a signal value that is mapped to the range in which the value of signal R4 belongs. According to the present example, the first gain adjustment signal is signal SG1. After the first signal value is identified, signal SG1 may be set to the identified first signal value.

At step 290, processing circuitry 256 identifies a second signal value and sets a second gain adjustment signal to the identified second signal value. The second signal value may be identified based on a second data structure, such as data structure 270. In the example of sensing system 100, the second signal value may be identified by: (i) identifying the value of signal R4, (ii) performing a search of data structure 270 based on the value of signal R4, (iii) identifying, as a result of the search, a signal value that is mapped to the range in which the value of signal R4 belongs. According to the present example, the second gain adjustment signal is signal SG2. After the second signal value is identified, signal SG2 may be set to the identified second signal value.

At step 291, the first gain adjustment signal is applied at the gain control terminal of a first programmable gain amplifier. According to the present example, signal SG1 is applied at the gain control terminal of PGA 202.

At step 292, the second gain adjustment signal is applied at the gain control terminal of a second programmable gain amplifier. According to the present example, signal SG2 is applied at the gain control terminal of PGA 207.

At step 293, an output signal is generated based on the first magnetic field signal and the second magnetic field signal. The output signal is generated after the gain of the first and second magnetic field signals is adjusted. According to the present example, the output signal is signal OUT (shown in FIG. 2B).

Although in the example of FIG. 2G, lookup tables (i.e., data structures 260 and 270) are used to identify the values of signals SG1 and SG2, alternative implementations are possible in which digital logic is used to implement the mappings between signal R4 and the values of signals SG1 and SG2. The digital logic may be part of processing circuitry 256 and it may map each of a plurality of first ranges for the value of signal R4 to a different respective value of signal SG1. Furthermore, the digital logic may map each of a plurality of second ranges for the value of signal R4 to a different respective value of signal SG2. Moreover, in some implementations, the mapping between ranges for the value of signal R4 and respective values of signals SG1 and SG2 may be performed by using analog circuitry. The analog circuitry may be part of processing circuitry 256. The analog circuitry may map each of a plurality of first ranges for the value of signal R4 to a different respective value of signal SG1. Furthermore, the analog circuitry may map each of a plurality of second ranges for the value of signal R4 to a different respective value of signal SG2. Although in the example of FIG. 2G the values of signals SG1 and SG2 are determined based on signal R4, alternative implementations are possible in which the values of signals SG1 and SG2 are determined based on signal MR and/or any other signal that is at least in part generated by sensing elements 250. Although in the present example, the gains of PGAs 207 and 202 are controlled with different gain adjustment signals, alternative implementations are possible in which signal SG1 is used to control the gain of both of PGAs 207 and 202.

FIGS. 3A-B illustrate aspects of the operation of the implementation of sensing system 100 which is shown in FIG. 2A. Specifically, FIGS. 3A-B contrast the performance of sensing system 100 when circuit 104 is disabled with the performance of sensing system 100 when circuit 104 is enabled and used to dynamically adjust the gain of PGA 212. Together, FIGS. 3A-B illustrate that the use of circuit 104 to adjust the gain of PGA 212 could substantially improve the linearity of the response of sensor 102.

FIG. 3A is a graph showing aspects of the operation of sensing system 100 when circuit 104 is disabled. In the example of FIG. 3A, signal SG1 is set to a constant value (e.g., ‘0.1V’), and its value is not changed based on the value of signal MR. Shown in FIG. 3A is a graph of the actual magnetic field H that is incident on sensing elements 210 and sensing elements 230. The graph of the magnetic field H is represented by a dotted line. Shown in FIG. 3A is also a graph of signal A1, which represents the magnetic field that is measured by sensing elements 210. The graph of signal A1 is represented by a solid line. Further shown in FIG. 3A is a graph of the linearity error in signal A1. The graph of the linearity error is represented by a dashed line. FIG. 3A illustrates that the linearity error can reach in excess of 30% when circuit 104 is not used to dynamically adjust the gain of PGA 212.

FIG. 3B is a graph showing aspects of the operation of sensing system 100 when circuit 104 is enabled and used to dynamically adjust the gain of PGA 212. In the example of FIG. 3B, the value of signal SG1 is varied based on the value of signal MR, in the manner discussed above with respect to FIGS. 2B and 2F. Shown in FIG. 3B is a graph of the actual magnetic field H that is incident on sensing elements 210 and sensing elements 230. The graph of the magnetic field H is represented by a dotted line. Shown in FIG. 3B is also a graph of signal A1, which represents the magnetic field that is measured by sensing elements 210. The graph of signal A1 is represented by a solid line. Further shown in FIG. 3B is a graph of the linearity error in signal A1. The graph of the linearity error is represented by a dashed line. FIG. 3B illustrates that the linearity error can be limited to about 6% when circuit 104 is used to dynamically adjust the gain of PGA 212.

In one aspect, circuit 104 may adjust the gain of PGA 212 to compensate for variations in the gain of sensing elements 210 that are caused by temperature or aging, for example. The compensation allows sensing elements 210 to operate at a higher linear range than otherwise. Enabling sensor 102 to operate at a higher liner range is advantageous because it may improve the accuracy of sensor 102.

According to the example of FIG. 2A, sensing elements 210 includes one or more tunnel magnetoresistance elements (TMRs). Sensing elements 210 may be connected with each other in a bridge circuit, in series, or in any other suitable manner. Furthermore, according to the present example, sensing elements 230 includes one or more Hall elements, such as vertical Hall elements. Sensing elements 230 may be connected with each other in a bridge circuit, in series, or in any other suitable manner. In general, Hall elements may provide a very stable linear range, in comparison to TMR elements, while TMR elements have higher sensitivity to magnetic field. In this regard, in some circumstances, using TMR elements in sensor 102 and Hall elements in circuit 104 is advantageous because it may achieve higher sensitivity and higher linear response than when Hall or TMR elements are used in sensor 102 and circuit 104 is omitted, thus resulting in a highly accurate sensor.

Although, in the present example, sensing elements 210 are implemented by using TMR elements, the present disclosure is not limited thereto. For example, any of sensing elements 210 may include a Hall Effect element, for example, a vertical Hall element, and a Circular Vertical Hall (CVH) element. Additionally or alternatively, any of sensing elements 210 may include a magnetoresistance element such as Indium Antimonide (InSb), a giant magnetoresistance (GMR) element, an anisotropic magnetoresistance element (AMR), and a magnetic tunnel junction (MTJ). Stated succinctly the present disclosure is not limited to any specific implementation of sensing elements 210.

Although, in the present example, sensing elements 230 are implemented by using Hall elements, the present disclosure is not limited thereto. For example, any of sensing elements 230 may include a magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). Stated succinctly the present disclosure is not limited to any specific implementation of sensing elements 230. Sensing elements 210 and 230 may be implemented by using the same type of sensing element or different types of sensing elements. For example, both sensing elements 210 and 230 may be implemented by using TMR elements.

As noted above, circuit 104 may implement a mapping between various values of the output of sensing elements 230 and corresponding values of the gain adjustment signal SG1. An example of the mapping is shown in FIG. 2C, which illustrates that each of a plurality of ranges of the output of sensing elements 230 may be mapped to a different corresponding value of signal SG1. In some implementations, the upper bound of each of the ranges may be selected to correspond to a magnetic flux density value (or value of signal R4) at which the linearity error of sensor 102 exceeds 6%, or another error threshold, when the value of signal SG1 that corresponds to the range is used to set the gain of PGA 212. So, for each entry in data structure 260, the value of signal SG1 that is part of that entry may yield 6% linearity error at the upper bound of the entry's range. The points where the linearity error of sensor 102 exceeds 6% or another value may be determined by conducting laboratory tests or simulations. The appropriate values of signal SG1 that correspond to each of the ranges may also be determined by conducting tests or simulations

In some implementations, sensing elements 201 (shown in FIG. 2B) may include one or more TMRs, sensing elements 206 may also include one or more TMRs, and sensing elements 250 may include one or more Hall elements. Sensing elements 201 may be connected with each other in a bridge circuit, in series, or in another suitable manner. Sensing elements 206 may be connected with each other in a bridge circuit, in series, or in another suitable manner. Sensing elements 250 may be connected with each other in a bridge circuit, in series, or in another suitable manner.

The present disclosure is not limited to any specific implementation of sensing elements 201, 206, and 250. In some implementations, any of sensing elements 201, 206, and 250 may be implemented by using one or more of a Hall element, a CVH element, a GMR element, a TMR element, an AMR element, an MTJ element, and/or any other suitable type of magnetic field sensing element. The type of sensing element that is used to implement sensing elements 201 may be the same as the type of sensing element used to implement sensing elements 206. Additionally or alternatively, the type of sensing element used to implement sensing elements 250 may be the same or different from the type of sensing element that is used to implement one or both of sensing elements 201 and 206.

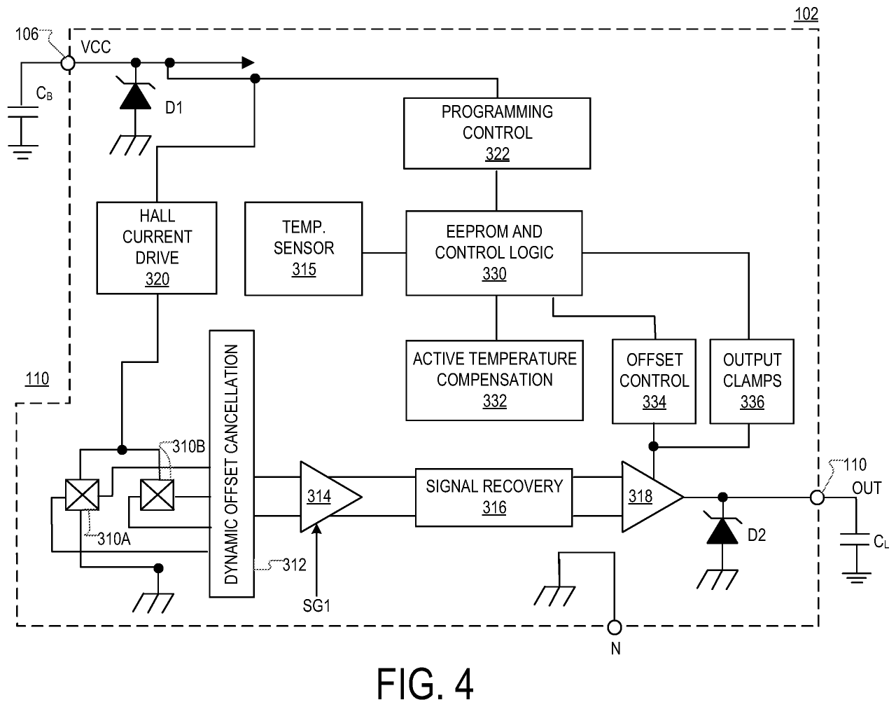

The use of a compensation circuit, such as circuit 104, is not limited to the sensor architecture which is shown in FIG. 2A. In general, a compensation circuit, such as circuit 104, could be used in any architecture that includes a PGA in its signal processing pipeline. The compensation circuit may be used to correct the gain of the PGA, irrespective of what architecture the PGA is part of or where in the pipeline the PGA is located. In this regard, FIG. 4, which is discussed further below, shows an example of another sensor architecture that can utilize the services of a compensation circuit to achieve an improved linear response.

FIG. 4 is a circuit diagram illustrating one possible implementation of the electronic circuitry of sensor 102. According to the example of FIG. 4, sensor 102 is a current sensor.

The sensor 102 may be configured to output a signal OUT that is proportional to ΔB=B_{R}−B_{L} where B_{R} represents a magnetic field incident on one of magnetic field sensing elements 310A-B and B_{L} represents a magnetic field incident on the other one of the sensing elements 310A-B. The sensor output OUT is also affected by the sensitivity, α, of the signal path and can be represented as follows:

$$VOUT = α \times Δ B \qquad ( 1 )$$

The relationship between the conductor current to be measured and the differential field ΔB can be represented by a coupling coefficient, K(f) as follows:

$$Δ B = K ( f ) \times I \qquad ( 2 )$$

It will be appreciated that coupling coefficient K(f) corresponds to coupling (e.g., transfer of energy, etc.) between sensing elements 310A-B and the conductor carrying the electrical current that is being measured.

As discussed above with respect to FIG. 1, sensor 102 may include a terminal 106 and a terminal 110. Terminal 106 is used for the input power supply or supply voltage for sensor 102. A bypass capacitor, C_{B}, can be coupled between the terminal 106 and ground. Terminal 106 can also be used for programming sensor 102. Terminal 110 is used for providing the output signal OUT to external circuits or systems and can also be used for programming sensor 102. An output load capacitance C_{L} is coupled between terminal 110 and ground. In the example of FIG. 4, sensor 102 can include a first diode D1 coupled between terminal 106 and ground and a second diode D2 coupled between terminal 110 and ground.

The driver circuit 320 may be configured to drive the sensing elements 310A-B. Magnetic field signals generated by the sensing elements 310A-B are coupled to a dynamic offset cancellation circuit 312, which is further coupled to an amplifier 314. The amplifier 314, according to the present example is a programmable gain amplifier (PGA), and its gain is controlled with signal SG1. Signal SG1 may be generated by a compensation circuit, such as the circuit 104 examples of which are shown in FIGS. 1 and 2A-B. The amplifier 314 is configured to generate an amplified signal for coupling to the signal recovery circuit 316. Dynamic offset cancellation circuit 312 may take various forms including chopping circuitry and may function in conjunction with offset control circuit 334 to remove offset that can be associated with the sensing elements 310A-B and/or the amplifier 314. For example, offset cancellation circuit 312 can include switches configurable to drive the magnetic field sensing elements (e.g., Hall plates) in two or more different directions such that selected drive and signal contact pairs are interchanged during each phase of the chopping clock signal and offset voltages of the different driving arrangements tend to cancel. A regulator (not shown) can be coupled between supply voltage VCC and ground and to the various components and sub-circuits of the sensor 102 to regulate the supply voltage.

A programming control circuit 322 is coupled between the terminal 106 and EEPROM and control logic circuit 330 to provide appropriate control to the EEPROM and control logic circuit. EEPROM and control logic circuit 330 determines any application-specific coding and can be erased and reprogrammed using a pulsed voltage. The offset control circuit 334 can generate and provide an offset signal to a push/pull driver circuit 318 (which may be an amplifier) to adjust the sensitivity and/or operating voltage of the driver circuit 318. The active temperature compensation circuit 332 can acquire temperature data from EEPROM and control logic circuit 330 via a temperature sensor 315 and perform necessary calculations to compensate for changes in temperature, if needed. Output clamps circuit 336 can be coupled between the EEPROM and control logic circuit 330 and the driver circuit 318 to limit the output voltage and for diagnostic purposes.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special-purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

A magnetic-field sensing element can be, but is not limited to, a Hall Effect element a magnetoresistance element, or an inductive coil. As is known, there are different types of Hall Effect elements, for example, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb). The phrase “set of magnetic field elements” shall mean “one or more magnetic field sensing elements”.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A device, comprising:
a magnetic field sensor including: (i) one or more first magnetic field sensing elements arranged to produce a first magnetic field signal in response to a magnetic field, (ii) a programmable gain amplifier (PGA) that is configured to amplify the first magnetic field signal to produce an amplified signal, and (iii) a first circuitry that is configured to generate an output signal based on the amplified signal; and
a compensation circuit including: (i) one or more second magnetic field sensing elements that are arranged to produce a second magnetic field signal in response to the magnetic field, and (ii) a second circuitry that is configured to generate a gain adjustment signal based on the second magnetic field signal, the second circuitry being configured to apply the gain adjustment signal at a control terminal of the PGA,
wherein the gain adjustment signal is generated based on a map that maps each of a plurality of values of the second magnetic field signal to a respective value of the gain adjustment signal, the map being implemented by the second circuitry, and
wherein the magnetic field sensor and the compensation circuit are disposed in a same package.

2. The device of claim 1, wherein the second circuitry includes a digital processing circuitry and the map is implemented as part of a firmware of the digital processing circuitry.

3. The device of claim 2, further comprising one or more terminals for updating the map.

4. The device of claim 1, wherein the second circuitry includes at least one of analog circuitry and/or digital circuitry.

5. The device of claim 1, wherein the first circuitry is configured to adjust a gain and/or offset of the amplified signal based on at least one of temperature, humidity, and/or stress.

6. The device of claim 1, wherein applying the gain adjustment signal at a control terminal of the PGA causes a gain of the PGA to increase or decrease based on a strength of the magnetic field at a location of the one or more second magnetic field sensing elements.

7. The device of claim 1, wherein the magnetic field sensor and the compensation circuit are formed on a same substrate.

8. The device of claim 1, wherein:
the map is implemented in hardware by using analog circuitry and/or digital logic,
each of the first magnetic field sensing elements includes one of a Hall effect element, a giant magnetoresistor (GMR), or a tunnel magnetoresistor (TMR), and
each of the second magnetic field sensing elements includes one of a Hall effect element, a giant magnetoresistor (GMR), or a tunnel magnetoresistor (TMR).

9. A device, comprising:
a magnetic field sensor including a first channel, a second channel, and a first circuitry, wherein: (i) the first channel includes one or more first magnetic field sensing elements that are configured to produce a first magnetic field signal in response to a magnetic field and a first programmable gain amplifier (PGA) that is configured to amplify the first magnetic field signal to produce a first amplified signal, (ii) the second channel includes one or more second magnetic field sensing elements that are configured to produce a second magnetic field signal in response to the magnetic field and a second PGA that is configured to amplify the second magnetic field signal to produce a second amplified signal, and (iii) the first circuitry is configured to generate an output signal based on the first amplified signal and the second amplified signal; and
a compensation circuit including one or more third magnetic field sensing elements that are arranged to produce a third magnetic field signal in response to the magnetic field, and a second circuitry that is configured to generate, based on the third magnetic field signal, a first gain adjustment signal and a second gain adjustment signal, the second circuitry being configured to apply the first gain adjustment signal at a first control terminal of the first PGA, the second circuitry being configured to apply the second gain adjustment signal at a second control terminal of the second PGA,
wherein for at least one value of the third magnetic field signal, the first gain adjustment signal and the second gain adjustment signal have different values.

10. The device of claim 9, wherein:
the first gain adjustment signal is generated based on a first map that maps each of a first plurality of values of the third magnetic field signal to a respective value of the first gain adjustment signal, and
the second gain adjustment signal is generated based on a second map that maps each of a second plurality of values of the third magnetic field signal to a respective value of the second gain adjustment signal.

11. The device of claim 10, wherein the second circuitry includes a digital processing circuitry and the first map and the second map are implemented as part of a firmware of the digital processing circuitry.

12. The device of claim 10, further comprising one or more terminals for updating the first map and the second map.

13. The device of claim 10, wherein:
the first map maps each of a first plurality of ranges of the first magnetic field signal to a corresponding value of the first gain adjustment signal, and
the second map maps each of a second plurality of ranges of the second magnetic field signal to a corresponding value of the second gain adjustment signal.

14. The device of claim 10, wherein each of the first map and the second map is implemented in hardware by using analog and/or digital circuitry.

15. The device of claim 9, wherein the magnetic field sensor and the compensation circuit are disposed in a same package.

16. The device of claim 9, wherein:
each of the first magnetic field sensing elements includes one of a Hall effect element, a giant magnetoresistor (GMR), or a tunnel magnetoresistor (TMR),
each of the second magnetic field sensing elements includes one of a Hall effect element, a giant magnetoresistor (GMR), or a tunnel magnetoresistor (TMR), and
each of the second magnetic field sensing elements includes one of a Hall effect element, a giant magnetoresistor (GMR), or a tunnel magnetoresistor (TMR).

17. A device, comprising:
a magnetic field sensor including: (i) one or more first magnetic field sensing elements arranged to produce a first magnetic field signal in response to a magnetic field, (ii) a programmable gain amplifier (PGA) that is configured to amplify the first magnetic field signal to produce an amplified signal, and (iii) a first circuitry that is configured to generate an output signal based on the amplified signal; and
a compensation circuit including: (i) one or more second magnetic field sensing elements that are arranged to produce a second magnetic field signal in response to the magnetic field, and (ii) a second circuitry that is configured to adjust a gain of the PGA based on the second magnetic field signal, thereby causing a gain of the PGA to be increased or decreased based on a strength of the magnetic field at a location of the one or more second magnetic field sensing elements.

18. The device of claim 17, wherein adjusting the gain of the PGA includes generating a gain adjustment signal and applying the gain adjustment signal at a control terminal of the PGA, the gain adjustment signal being generated by using a map that maps each of a plurality of values of the second magnetic field signal to a respective value of the gain adjustment signal.

19. The device of claim 17, wherein the magnetic field sensor and the compensation circuit are disposed in a same package.

20. The device of claim 17, wherein the first circuitry is configured to adjust a gain and/or offset of the amplified signal based on at least one of temperature, humidity, and stress.

21. The device of claim 17, wherein:
each of the first magnetic field sensing elements includes one of a Hall effect element, a giant magnetoresistor (GMR), or a tunnel magnetoresistor (TMR), and
each of the second magnetic field sensing elements includes one of a Hall effect element, a giant magnetoresistor (GMR), or a tunnel magnetoresistor (TMR).

22. A method for use in a magnetic field sensor, comprising:
generating a first magnetic field signal by using one or more first magnetic field sensing elements, the first magnetic field signal being generated in response to a magnetic field;
generating a second magnetic field signal by using one or more second magnetic field sensing elements that are formed on a same substrate as the first magnetic field sensing elements, the second magnetic field signal being generated in response to the magnetic field, and
generating an output signal at least in part by adjusting a gain of the first magnetic field signal based on the second magnetic field signal.

23. The method of claim 22, wherein adjusting the gain of the first magnetic field signal includes generating a gain adjustment signal based on the second magnetic field signal and applying the gain adjustment signal at a control terminal of a programmable gain amplifier (PGA) that is arranged to amplify the first magnetic field signal.

24. The method of claim 22, wherein adjusting the gain of the first magnetic field signal includes identifying a value for a gain adjustment signal, setting the gain adjustment signal to the identified value, and applying the gain adjustment signal at a control terminal of a programmable gain amplifier (PGA) that is arranged to amplify the first magnetic field signal, the value for the gain adjustment signal being identified based on the second magnetic field signal by using a map that maps each of a plurality of ranges of the second magnetic field signal to a corresponding value of the gain adjustment signal, the map being implemented as one or more of a firmware of the magnetic field sensor, analog circuitry that is part of the magnetic field sensor, and/or digital circuitry that is part of the magnetic field sensor.

25. A system, comprising:
means for generating a first magnetic field signal in response to a magnetic field;
means for generating a second magnetic field signal in response to the magnetic field, and
means for generating an output signal at least in part by adjusting a gain of the first magnetic field signal based on the second magnetic field signal, wherein the adjusting is performed based on a map that maps each of a plurality of ranges of the second magnetic field signal to a respective value of a gain adjustment signal applied at a control terminal of a programmable gain amplifier (PGA), the PGA being arranged to amplify the first magnetic field signal.
